(19) United States
(12) Patent Application Publication
(10) Pub. No.: US 2015/0008795 A1
(43) Pub. Date: Jan. 8, 2015

(54) PIEZOELECTRIC POWER GENERATOR

(71) Applicants: Korea Electronics Technology Institute, Seongnam (KR); Hyundai Motor Company, Seoul (KR)

(72) Inventors: Chan Hee Kang, Bucheon (KR); Hyunsoo Sohn, Suwon (KR); Sun Mi Oh, Bucheon (KR); Chan-Sei Yoo, Uiwang (KR); Seung-Ho Han, Yongin (KR); Hyeung-Gyu Lee, Seoul (KR); Hyung-Won Kang, Seoul (KR)

(73) Assignees: KOREA ELECTRONICS TECHNOLOGY INSTITUTE, Seongnam (KR); HYUNDAI MOTOR COMPANY, Seoul (KR)

(21) Appl. No.: 14/142,872

(22) Filed: Dec. 29, 2013

(30) Foreign Application Priority Data
Jul. 2, 2013 (KR) 10-2013-0077308

(51) Int. Cl. H01L 41/113

(52) U.S. Cl. CPC H01L 41/1136
USPC 310/331

(57) ABSTRACT

A piezoelectric power generator can be used regardless of the size of the parts, and can position the mass center of a mass at the center by disposing the free ends of cantilevers opposite each other when connecting a plurality of cantilevers in series. The piezoelectric power generator is a morph structure cantilever piezoelectric power generator having at least two cantilevers disposed with their free ends opposite to each other, and a mass that is one body provided for bending of the cantilevers.

### CROSS-REFERENCE TO RELATED APPLICATION

This application claims priority under 35 U.S.C. §119(a) to and the benefit of Korean Patent Application No. 10-2013-0077308 filed in the Korean Intellectual Property Office on Jul. 2, 2013, the entire contents of which are incorporated herein by reference.

### BACKGROUND

(a) Field of the Invention

The present invention relates to a piezoelectric power generator that converts mechanical energy into electric energy.

(b) Description of the Related Art

In general, piezoelectric power generators are power generators using a piezoelectric effect for converting external mechanical energy (e.g., wind, vibration of devices, and actions of a human) into electric energy.

The piezoelectric device showing the piezoelectric effect is fragile, and thus affected by external mechanical energy. Since the piezoelectric devices are fragile, the piezoelectric devices are manufactured as a cantilever having a morph structure formed by integrally bonding a high elastic substrate (e.g., metal or plastic) to prevent the piezoelectric devices from being broken, when deforming the piezoelectric devices with an external force.

FIG. 1 (RELATED ART) conceptually shows an example of a piezoelectric power generator manufactured as a morph structure cantilever.

In FIG. 1, reference numerals 12 and 14 indicate piezoelectric devices, 20 indicates a substrate preventing the piezoelectric devices 12 and 14 from breaking, 30 indicates a cantilever formed by bonding a piezoelectric device with a substrate, and 40 indicates a mass that causes deformation of the piezoelectric devices 12 and 14 by inducing bending, corresponding to an external force. Hereinafter, the cantilever is defined as a structure with a piezoelectric device and a substrate bonded.

In such a piezoelectric power generator, the morph structure is classified into a mono morph (uni-morph) and a bi-morph (shown in FIG. 1) in accordance with the number of piezoelectric devices around the substrate 20 stated above.

The morph structure cantilever is the most typical structure among piezoelectric devices.

When an external force is applied to a morph structure cantilever with the piezoelectric devices 12 and 14 and the substrate bonded, as shown in FIG. 1, AC electricity is generated by the piezoelectric effect. The generated AC electricity is converted into DC electricity by a rectifier circuit and then charged in a high-capacity capacitor or a battery, such that it can be used when needed.

For a common morph structure cantilever, the piezoelectric device is deformed by fixing one end and mounting a mass on the other end, and then inducing bending of the cantilever with respect to an external force.

In particular, in a morph structure cantilever of a piezoelectric power generation module according to an exemplary embodiment of the present invention, bending due to an external force can be increased by mounting a mass on the free end. The bending of the morph structure cantilever can be increased by increasing the weight of the mass, such that the corresponding large deformation of the piezoelectric device can increase the amount of power generation.

However, the increase in weight of the mass causes an increase in height of the piezoelectric power generation module, so there is a limit in increasing the weight of the mass.

In particular, when the weight of the mass is increased to increase the amount of power generation of the piezoelectric power generation module in the exemplary embodiment of the present invention, the size and height of the mass are increased, and the increase in height of the mass means that the entire size and height of a piezoelectric power generator are increased. As described above, as the size and height of the piezoelectric power generator increase, the piezoelectric power generator is difficult to use as the power generator for small parts (e.g. TPMS (Tire Pressure Monitoring System)) for a spatial limit.

On the other hand, the amount of power generation of the piezoelectric power generator can be increased by connecting power generators in parallel, in which there may be a problem in that the mass center of the power generation module is biased to a side when the free ends of the cantilevers are arranged in the same direction, that is, the mass is biased to the free end and thus the generated voltage is not stable.

The Description of the Related Art is made to help understanding the background of the present invention and may include matters out of the related art known to those skilled in the art.

The above information disclosed in this Background section is only for enhancement of understanding of the background of the invention and therefore it may contain information that does not form the prior art that is already known in this country to a person of ordinary skill in the art.

### SUMMARY

The present invention provides a piezoelectric power generator having advantages of being able to be easily used regardless of the size of the parts using the piezoelectric power generator, and to position the mass center of a mass at the center by disposing the free ends of cantilevers opposite each other when connecting a plurality of cantilevers in series.

An exemplary embodiment of the present invention provides a morph structure cantilever piezoelectric power generator, which may include at least two cantilevers disposed with their free ends opposite to each other, and a mass that is one body provided for bending of the cantilevers.

The piezoelectric power generator may further include free end supports disposed on the mass to support the free ends and having a ring shape such that the free ends are movably supported on the mass when the cantilevers bend.

The free end supports may be fixed to the mass by bolts or an adhesive.

The piezoelectric power generator may further include fixed end supports that fix the fixed ends of the cantilevers, and the fixed ends may be fixed to the fixed end support by bolts or an adhesive.

The masses may be stacked at least in two layers.

The cantilevers may be electrically connected in parallel.

The masses stacked at least in two or more layers may be electrically connected in parallel.

The mass may have a symmetric shape such as disk and a rectangle.

As described above, according to an exemplary embodiment of the present invention, a piezoelectric power generator can be easily used regardless of the size of the parts using the piezoelectric power generator.

Further, according to an exemplary embodiment of the present invention, since it is possible to position the mass center of the mass at the center by connecting a plurality of cantilevers of a piezoelectric power generator such that the free ends of the cantilevers are opposite each other, power can be stably and efficiently generated.

### BRIEF DESCRIPTION OF THE DRAWINGS

FIG. 1 (RELATED ART) is a conceptual schematic diagram of a common morph structure cantilever piezoelectric power generator.

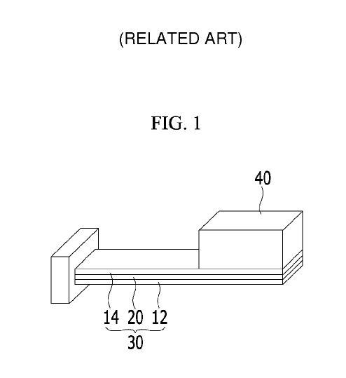

FIG. 2 is an exploded perspective view of a piezoelectric power generator according to an exemplary embodiment of the present invention.

FIG. 3 is a schematic diagram showing the shape of a free end support of a cantilever of the piezoelectric power generator according to an exemplary embodiment of the present invention.

FIG. 4 is a schematic diagram of the external appearance of a piezoelectric power generator having a single layer structure according to an exemplary embodiment of the present invention.

FIG. 5 is a schematic diagram of the external appearance of a piezoelectric power generator having a multilayer structure according to an exemplary embodiment of the present invention.

FIG. 6 is conceptual diagram illustrating the operation of the piezoelectric power generator according to an exemplary embodiment of the present invention.

### DETAILED DESCRIPTION OF THE EMBODIMENTS

The present invention will be described more fully hereinafter with reference to the accompanying drawings, in which exemplary embodiments of the invention are shown. The present invention may be implemented in various ways and is not limited to the exemplary embodiments described herein.

The unrelated parts to the description of the exemplary embodiments are not shown to make the description clear and like reference numerals designate like element throughout the specification.

Further, in the following exemplary embodiments, the components having the same configuration are designated by the same reference numerals and described in the first exemplary embodiment, and only other configurations different from the first exemplary embodiment are described in the other exemplary embodiments. The size and thickness of the configurations are optionally shown in the drawings for the convenience of description and the present invention is not limited to the drawings.

The thicknesses are expanded to make the structure of the piezoelectric power generator clear in the drawings. Further, in the drawings, some of the thicknesses and sizes are exaggerated for the convenience of description.

Throughout the present specification, unless explicitly described otherwise, “including” any components will be understood to imply the inclusion of other components rather than the exclusion of any other components.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

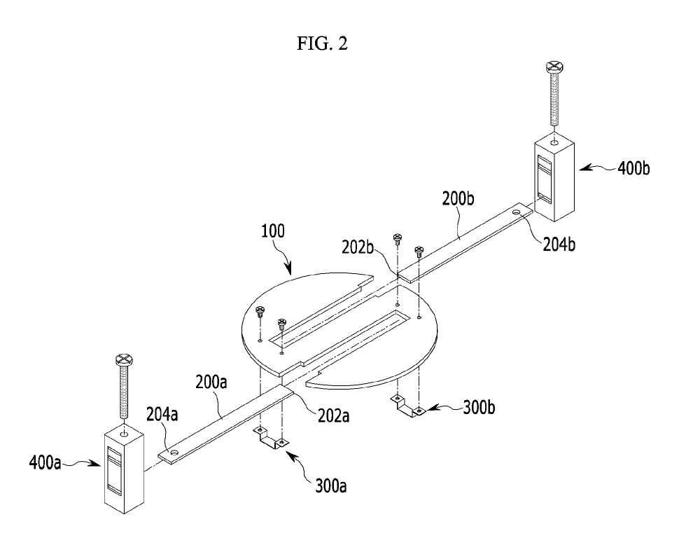

Hereinafter, a piezoelectric power generator according to an exemplary embodiment of the present invention will be described in detail with reference to FIGS. 2 to 7.

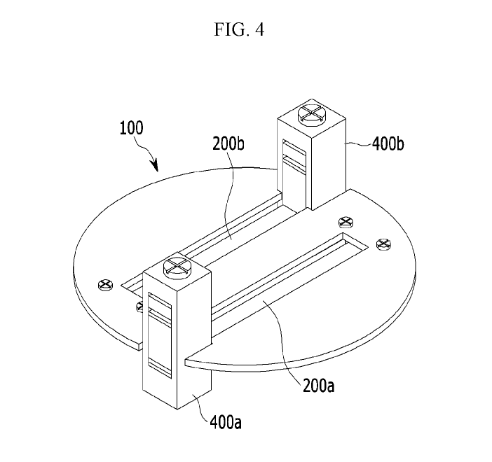

FIG. 2 is an exploded perspective view of a piezoelectric power generator according to an exemplary embodiment of the present invention, and FIG. 4 is a perspective view of the external appearance of a piezoelectric power generator having a single layer structure according to an exemplary embodiment of the present invention.

A piezoelectric power generator according to an exemplary embodiment of the present invention is a piezoelectric power generator in which the free ends of cantilevers are arranged opposite each other so as to generate maximum power in a limited space.

A piezoelectric power generator according to an exemplary embodiment of the present invention, which is a morph structure cantilever piezoelectric power generator, may include two or more cantilevers 200a and 200b disposed with their free ends opposite each other, and a mass 100 that is one body provided for bending of the cantilevers 200a and 200b.

The mass 100 preferably is a disk, but it should be understood that the scope of the present invention is not limited thereto. The mass 100 may be formed in a rectangular and hexagonal shape, other than the disk shape, in consideration of design.

The cantilevers 200a and 200b have grooves corresponding to the number of the cantilevers such that the cantilevers are disposed with regular intervals without interference in bending.

Although two cantilevers are shown in FIG. 2, it should be understood that the scope of the present invention is not limited thereto. In particular, although two or more cantilevers (i.e., at least two cantilevers) may be provided in an exemplary embodiment of the present invention, it is assumed in herein that two cantilevers are provided for the convenience of description.

The free ends 202a and 202b of the cantilevers are movably supported on the mass 100 by free end supports 300a and 300b.

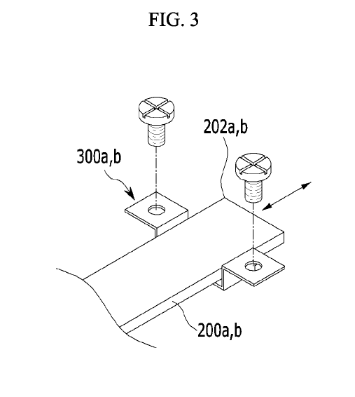

In particular, the free ends 202a and 202b of the cantilevers can move in the direction of an arrow from the free end supports 300a and 300b having a curved ring shape, as shown in FIG. 3.

Although the free end supports 300a and 300b are curved in FIGS. 2 and 3, it should be understood that the scope of the present invention is not limited thereto. The free end support 300a and 300b may be formed in various shapes such as the curved shape and a rounded shape.

The free end supports 300a and 300b may be fixed to the mass 100 by bolts, as shown in the figures. Alternatively, the free end supports 300a and 300b may be bonded to the mass 100 by an adhesive in consideration of design.

As shown in FIG. 2, the cantilever free ends 202a and 202b supported by the free end supports 300a and 300b are disposed opposite each other. Accordingly, as the mass 100 moves, the mass center of the mass 100 moves the center, as shown in FIG. 7, such that the piezoelectric power generator can stably generate power.

The fixed ends 204a and 204b of the cantilevers are fixed by fixed end supports 400a and 400b. The scope of the present invention can be applied to the fixed end supports 400a and 400b regardless of the form, shape, and structure, as long as they can fix and support the fixed ends 204a and 204b of the cantilevers 200a and 200b.

The cantilever fixed ends 204a and 204b are fixed to the fixed ends 400a and 400b by bolts, as shown in the figures. Further, the cantilever fixed ends 204a and 204b may be fixed to the fixed ends 400a and 400b by an adhesive in consideration of design.

Obviously, the two cantilevers shown in FIGS. 2 and 4 can be electrically connected in parallel and output necessary power.

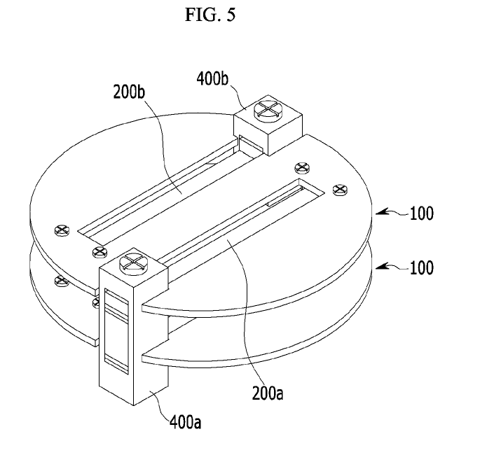

FIG. 5 is a schematic diagram of the external appearance of a piezoelectric power generator having a multilayer structure according to an exemplary embodiment of the present invention.

The piezoelectric power generator having a multilayer structure shown in FIG. 5 has a structure in which the piezoelectric power generators shown in FIGS. 2 and 4 are stacked in two layers. This structure can be easily achieved by fixing the cantilever fixed ends in two layers on the fixed end supports, which would be apparent to those skilled in the art.

It would be apparent to those skilled in the art that the cantilevers in masses in the multilayer structure shown in FIG. 5 can be electrically connected in parallel and output necessary power.

The operation of the piezoelectric power generator having the configuration according to an exemplary embodiment of the present invention is as follows.

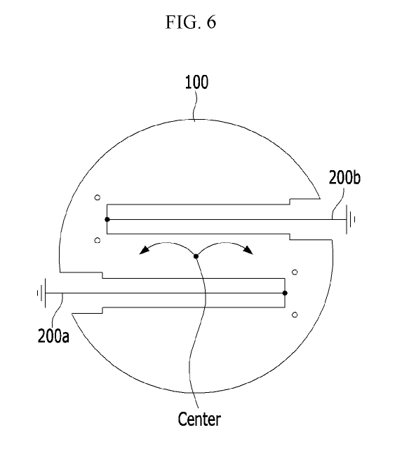

For example, when mechanical energy (e.g. vibration of a device) is applied to the disk, which is the mass 100 of the piezoelectric power generator according to an exemplary embodiment of the present invention, the cantilevers 200a, b are bent in the opposite directions from the disk mass 100 by vertical vibration of the disk, as shown in FIG. 6, and accordingly, electric energy is generated in the piezoelectric device.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A morph structure cantilever piezoelectric power generator comprising:
at least two cantilevers with their free ends opposite each other; and
a mass that is one body provided for bending of the cantilevers.

2. The piezoelectric power generator of claim 1, further comprising free end supports disposed on the mass to support the free ends, and having a ring shape such that the free ends are movably supported on the mass when the cantilevers bend.

3. The piezoelectric power generator of claim 2, wherein the free end supports are fixed to the mass by bolts or an adhesive.

4. The piezoelectric power generator of claim 1, further comprising
fixed end supports that fix the fixed ends of the cantilevers,
wherein the fixed ends are fixed to the fixed end support by bolts or an adhesive.

5. The piezoelectric power generator of claim 2, wherein the masses are stacked at least in two layers.

6. The piezoelectric power generator of claim 2, wherein the cantilevers are electrically connected in parallel.

7. The piezoelectric power generator of claim 5, wherein the masses stacked in at least two layers are electrically connected in parallel.

8. The piezoelectric power generator of claim 1, wherein the mass has a symmetric shape such as disk and a rectangle.

9. A cantilever piezoelectric power generator comprising:
at least two cantilevers with their free ends opposite each other;
a mass that is one body provided for bending of the cantilevers; and
free end supports disposed on the mass to support the free ends, and having a ring shape such that the free ends are movably supported on the mass when the cantilevers bend.

10. The piezoelectric power generator of claim 9, wherein the free end supports are fixed to the mass by bolts or an adhesive.

11. The piezoelectric power generator of claim 9, further comprising
fixed end supports that fix the fixed ends of the cantilevers, wherein the fixed ends are fixed to the fixed end support by bolts or an adhesive.

12. The piezoelectric power generator of claim 9, wherein the masses are stacked at least in two layers.

13. The piezoelectric power generator of claim 9, wherein the cantilevers are electrically connected in parallel.

14. The piezoelectric power generator of claim 13, wherein the masses stacked in at least two layers are electrically connected in parallel.

15. The piezoelectric power generator of claim 9, wherein the mass has a symmetric shape such as disk and a rectangle.
